(19) United States
(12) Patent Application Publication
(10) Pub. No.: US 2024/0263053 A1
(43) Pub. Date: Aug. 8, 2024

(54) RESIN COMPOSITION, ADHESIVE MEMBER, AND DISPLAY DEVICE

(71) Applicant: Samsung Display Co., Ltd., Yongin-si (KR)

(72) Inventor: Tetsuya FUJIWARA, Yokohama (JP)

(21) Appl. No.: 18/426,062

(22) Filed: Jan. 29, 2024

(30) Foreign Application Priority Data
Feb. 6, 2023 (KR) 10-2023-0015792

(51) Int. Cl. C09J 133/06; C08F 220/18; C09J 4/00; H01L 33/52; H05K 5/03; H10K 59/80

(52) U.S. Cl. CPC C09J 133/066; C08F 220/1808; C08F 220/1811; C09J 4/00; H05K 5/03; H01L 33/52; H10K 59/873

(57) ABSTRACT

A resin composition including a urethane (meth)acrylate oligomer containing two or more (meth)acryloyl groups, a hydroxy group-containing (meth)acrylate, and an alicyclic (meth)acrylate having a glass transition temperature of about 80° C. or greater, wherein the resin composition includes the urethane (meth)acrylate oligomer in a specific amount and the hydroxy group-containing (meth)acrylate in a specific concentration, and thus has a glass transition temperature of about −20° C. or greater and at most (e.g., less than) about 20° C. once cured is provided. An adhesive member and a display device including a cured product of the resin composition are provided.

### CROSS-REFERENCE TO RELATED APPLICATIONS

This application claims priority to and the benefit of Korean Patent Application No. 10-2023-0015792, filed on Feb. 6, 2023, the entire content of which is hereby incorporated by reference.

### BACKGROUND

### 1. Field

One or more aspects of embodiments of the present disclosure relate to a resin composition, an adhesive member, and a display device. For example, a resin composition, an adhesive member including a cured product thereof, and a display device.

### 2. Description of the Related Art

Various types (kinds) of display devices utilized for multimedia devices such as a television set, a mobile phone, a tablet computer, a navigation system, and a game console are being developed. An adhesive resin utilized to form an adhesive member applied to display devices (of one or more suitable types (kinds)) should have excellent or suitable coating properties for the adhesive members of the display devices (of one or more suitable types (kinds)).

For example, when bonding an adhesive resin with an adhesive member of a display device, unintended mistakes can cause loss to the materials of construction. For example, when air bubbles and/or foreign substances are mixed, (e.g., accidentally included), during bonding and/or misaligned bonding positions occur (e.g., upon bonding between the adhesive resin and the adhesive member of the display device), the adhesive resin and the adhesive member of the display device are discarded, and accordingly, there is a need or desire to resolve the concerns.

### SUMMARY

One or more aspects of embodiments of the present disclosure are directed toward an adhesive member having excellent or suitable adhesion at high temperature and humidity conditions, and a resin composition capable of providing the adhesive member.

The present disclosure also provides a display device including the adhesive member described herein, and thus having excellent or suitable durability even at high temperature and humidity conditions.

One or more embodiments of the present disclosure provides a resin composition including a urethane (meth)acrylate oligomer containing two or more (meth)acryloyl groups, and a monofunctional (meth)acrylate monomer. The monofunctional (meth)acrylate monomer includes a hydroxy group-containing (meth)acrylate and an alicyclic (meth)acrylate having a glass transition temperature of about 80° C. or greater. The resin composition includes the urethane (meth)acrylate oligomer in an amount of about 1 wt % or greater and about 10 wt % or less with respect to 100 wt % of the total resin composition, and the resin composition includes the hydroxy group-containing (meth)acrylate in an amount of about 5 mol % or greater and about 20 mol % or less with respect to 100 mol % of the total resin composition. The resin composition has a glass transition temperature of about −20° C. or greater and about 20° C. or less, once cured (e.g., upon curing).

In one or more embodiments, the resin composition may include the alicyclic (meth)acrylate in an amount of about 10 wt % or greater and about 40 wt % or less with respect to 100 wt % of the total resin composition.

In one or more embodiments, the hydroxy group-containing (meth)acrylate and the alicyclic (meth)acrylate may each have a weight average molecular weight of about 150 gram per mole (g/mol) to about 300 g/mol.

In one or more embodiments, the urethane (meth)acrylate oligomer may have a weight average molecular weight of about 10,000 g/mol or greater and about 40,000 g/mol or less.

In one or more embodiments, the resin composition may have a viscosity of at least about 5 millipascal second (mPa·s) or greater and about 20 mPa·s or less at 30° C.

In one or more embodiments, the monofunctional (meth)acrylate monomer may further include at least one of an alkyl (meth)acrylate or a heteroalicyclic (meth)acrylate.

In one or more embodiments, the alkyl (meth)acrylate and the heteroalicyclic (meth)acrylate may each have a weight average molecular weight of about 150 g/mol to about 300 g/mol.

In one or more embodiments, the resin composition may further include a photo-initiator. In one or more embodiments, the photo-initiator may include a radical polymerization initiator.

In one or more embodiments, the resin composition may be solvent-free (e.g., be prepared as a solvent-free type or kind) and may be photocurable.

In one or more embodiments of the present disclosure, an adhesive member is a cured product of a resin composition, wherein the resin composition includes a urethane (meth)acrylate oligomer containing two or more (meth)acryloyl groups, and a monofunctional (meth)acrylate monomer, the monofunctional (meth)acrylate monomer includes a hydroxy group-containing (meth)acrylate, and an alicyclic (meth)acrylate having a glass transition temperature of about 80° C. or greater, the resin composition includes the hydroxy group-containing (meth)acrylate in an amount of about 5 mol % or greater and about 20 mol % or less with respect to 100 mol % of the total resin composition and has a viscosity of about 5 mPa·s or greater and about 20 mPa·s or less at 30° C.

In one or more embodiments, the cured product (e.g., adhesive member) may have a haze of less than about 1% at a thickness of about 200 micrometer (μm) or less.

In one or more embodiments, the cured product (e.g., adhesive member) may have a haze change rate of about 2% or less in Equation 1, which is described elsewhere herein.

In one or more embodiments, the cured product (e.g., adhesive member) may have a moisture absorption rate of less than about 2% when exposed for about 72 hours at a temperature of about 85° C. and a humidity of about 85%.

In one or more embodiments, the cured product (e.g., adhesive member) may have a 180° peel force of about 400 gram-force per 25 millimeter (gf/25 mm) or greater with respect to a glass substrate or a polymer substrate after (e.g., when) the cured product (e.g., adhesive member) is exposed for about 72 hours at a temperature of about 85° C. and a humidity of about 85%.

In one or more embodiments of the present disclosure, a display device includes a display panel, a window provided on the display panel, and an adhesive member provided between the display panel and the window and including a polymer derived from a resin composition of one or more embodiments of the present disclosure.

In one or more embodiments, the display device may further a light control layer provided between the adhesive member and the window, and an optical adhesive layer provided between the light control layer and the window, wherein the optical adhesive layer may include a polymer derived from the resin composition described herein.

### BRIEF DESCRIPTION OF THE DRAWINGS

The accompanying drawings are included to provide a further understanding of the above and other aspects, features, and advantages of certain embodiments of the present disclosure are incorporated in and constitute a part of this specification. The drawings illustrate embodiments of the present disclosure and, together with the description, serve to explain principles of the present disclosure. In the drawings:

FIG. 1 is a perspective view showing a display device according to one or more embodiments of the present disclosure;

FIG. 2 is an exploded perspective view showing a display device according to one or more embodiments of the present disclosure;

FIG. 3 is a cross-sectional view showing a display device according to one or more embodiments of the present disclosure;

FIG. 4 schematically shows a method for manufacturing a display device according to one or more embodiments of the present disclosure;

FIG. 5 schematically shows a method for manufacturing a display device according to one or more embodiments of the present disclosure;

FIG. 6 schematically shows a method for manufacturing a display device according to one or more embodiments of the present disclosure;

FIG. 7 is a cross-sectional view showing a display device according to one or more embodiments of the present disclosure;

FIG. 8 is a cross-sectional view showing a display device according to one or more embodiments of the present disclosure; and

FIG. 9 is a perspective view of a vehicle including a display device according to one or more embodiments of the present disclosure.

### DETAILED DESCRIPTION

The present disclosure may be modified in many alternate forms, and thus specific embodiments will be exemplified in the accompanying drawings and described in more detail. In the drawings, like reference numerals refer to like elements throughout, and duplicative descriptions thereof may not be provided. In this regard, the present embodiments may have different forms and should not be construed as being limited to the descriptions set forth herein. Accordingly, the embodiments are merely described, by referring to the drawings, to explain aspects of the present description. It should be understood, however, that it is not intended to limit the present disclosure to the particular forms disclosed, but rather, is intended to cover all modifications, equivalents, and alternatives falling within the spirit and scope of the present disclosure.

As utilized herein, when an element (or a region, a layer, a portion, and/or the like) is referred to as being “on,” “connected to,” or “coupled to” another element, it indicates that the element may be directly provided on/connected to/coupled to the other element, or that a third element may be provided therebetween. Expressions such as “at least one of,” “one of,” and “selected from,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Like reference numerals refer to like elements. In some embodiments, in the drawings, the thickness, the ratio, and the dimensions of elements are exaggerated for an effective description of technical contents. The term “and/or,” includes all combinations of one or more of which associated configurations may define.

It will be understood that, although the terms first, second, etc. may be utilized herein to describe one or more suitable elements, these elements should not be limited by these terms. These terms are only utilized to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

In some embodiments, terms of “on lower side”, “above”, “on upper side”, and/or the like may be utilized to describe the relationships of the components shown in the drawings. The terms are utilized as a relative concept and are described with reference to the direction indicated in the drawings.

It should be understood that the terms “comprise,” “comprises,” “comprising,” “has,” “have,” “having,” “include,” “includes,” and/or “including,” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including chemical names and technical and scientific terms) utilized herein have the same meaning as commonly understood by one of ordinary skill in the art to which the present disclosure pertains. It is also to be understood that terms defined in commonly utilized dictionaries should be interpreted as having meanings consistent with the meanings in the context of the related art, and are expressly defined herein unless they are interpreted in an ideal or overly formal sense. Also, terms, such as those defined in commonly utilized dictionaries, should be interpreted as having a meaning that is consistent with their meaning in the context of the relevant art and should not be interpreted in an idealized or overly formal sense unless expressly so defined herein. Thus, a first element could be termed a second element without departing from the teachings of the present disclosure. Similarly, a second element could be termed a first element.

In this context, “consisting essentially of” means that any additional components will not materially affect the chemical, physical, optical or electrical properties of the semiconductor film.

As used herein, singular forms such as “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

As used herein, the term “and/or” includes any, and all, combination(s) of one or more of the associated listed items.

Further, in this specification, the phrase “on a plane,” or “plan view,” means viewing a target portion from the top, and the phrase “on a cross-section” means viewing a cross-section formed by vertically cutting a target portion from the side.

### Display Device

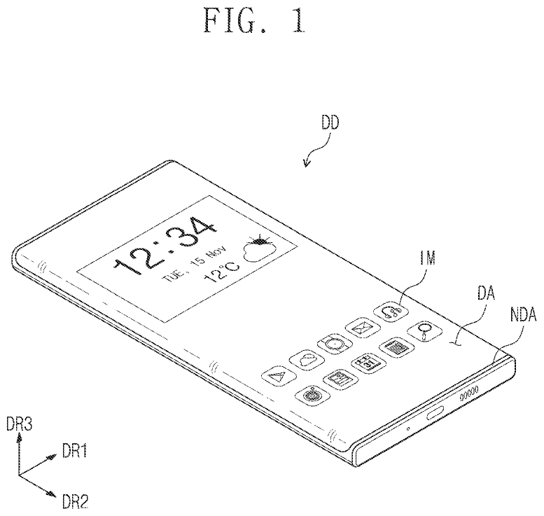

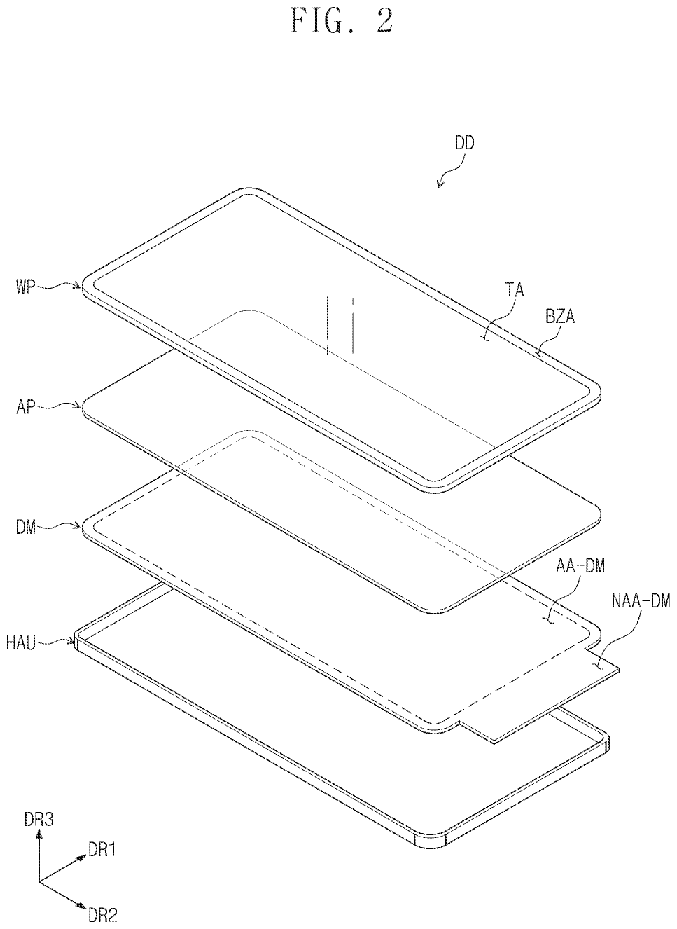

Hereinafter, an adhesive member of one or more embodiments of the present disclosure and a display device including the same will be described with reference to the accompanying drawings. FIG. 1 is a perspective view showing a display device of one or more embodiments. FIG. 2 is an exploded perspective view of a display device according to one or more embodiments.

A display device DD shown in FIG. 1 may be a device activated according to electrical signals. For example, the display device DD may be personal computers, laptop computers, personal digital terminals, game consoles, portable electronic devices, television sets, monitors, outdoor billboards, car navigation systems, or wearable devices, but is not limited thereto. In FIG. 1, as an example, a mobile phone is presented as the display device DD.

The display device DD according to one or more embodiments may display an image IM through a display region DA. The display region DA may include a plane defined by a first directional axis DR1 and a second directional axis DR2. The display region DA may further include a curved surface bent from one side of the plane defined by the first directional axis DR1 and the second directional axis DR2. The display device DD of one or more embodiments shown in FIG. 1 is illustrated to include two curved surfaces each bent from both (e.g., simultaneously) sides of the plane defined by the first directional axis DR1 and the second directional axis DR2. However, the shape of the display region DA is not limited thereto. For example, the display region DA may include only the plane defined by the first directional axis DR1 and the second directional axis DR2, and the display region DA may further include curved surfaces each bent from at least two sides of the plane defined by the first directional axis DR1 and the second directional axis DR2 (e.g., four curved surfaces each bent from four sides of the plane).

The display device DD of one or more embodiments may be flexible. The term “flexible” indicates a property of being bendable, and may include all from a structure being completely foldable to a structure being bendable up to several nanometers. For example, the display device DD may be a foldable display device. In some embodiments, the display device DD may be rigid.

A non-display region NDA may be a region adjacent to the display region DA. The non-display region NDA may surround the display region DA. Accordingly, the shape of the display region DA may be defined substantially by the non-display region NDA. However, this is presented as an example, and the non-display region NDA may be provided adjacent to only one side of the display region DA, or may not be provided. The display region DA may be provided in one or more suitable shapes and is not limited to any one embodiment.

FIG. 1 and the following drawings show the first to third directional axes DR1 to DR3, and directions indicated by the first to third directional axes DR1, DR2, and DR3 described herein are relative concepts, and may thus be changed to other directions. In some embodiments, the directions indicated by the first to third directional axes DR1, DR2, and DR3 may be described as first to third directions, and the same reference numerals may be utilized. The first directional axis DR1 and the second directional axis DR2 herein may be perpendicular to each other, and the third directional axis DR3 may be a normal direction with respect to a plane defined by the first directional axis DR1 and the second directional axis DR2.

A thickness direction of the display device DD may be parallel to the third directional axis DR3 which is a normal direction with respect to the plane defined by the first directional axis DR1 and the second directional axis DR2. As described herein, a front surface (or an upper surface, upper portion surface, upper side) and a rear surface (or a lower surface, lower portion surface, lower side) of members constituting the display device DD may be defined with respect to the third directional axis DR3. In some embodiments, as described herein, a direction in which the third directional axis DR3 extends is parallel to the thickness direction, and the front surface (or an upper surface, upper portion surface, upper side) indicates a surface (or direction) adjacent to a surface on which the image IM is displayed, and the rear surface (or a lower surface, lower portion surface, lower side) indicates a surface (or direction) spaced apart from a surface on which the image IM is displayed.

Referring to FIG. 2, the display device DD may include a display module DM, a window WP provided on the display module DM, and an adhesive member AP provided between the display module DM and the window WP. In some embodiments, the display device DD may further include a housing HAU accommodating the display module DM.

In the display device DD shown in FIGS. 1 and 2, the window WP and the housing HAU may be bonded together to form an outer portion of the display device DD. The housing HAU may be provided the display module DM. The housing HAU may include a material having a relatively higher rigidity. For example, the housing HAU may include a plurality of frames and/or plates formed of glass, plastic, or metal. The housing HAU may provide a set or predetermined place for accommodation. The display module DM may be accommodated in the accommodation place to be protected from external shocks.

The display module DM may be activated according to electrical signals. The display module DM may be activated to display the image IM (FIG. 1) on the display region DA (FIG. 1) of the display device DD. In the display module DM, an active region AA-DM and a peripheral region NAA-DM may be defined. The active region AA-DM may be a region activated according to electrical signals. The peripheral region NAA-DM may be a region adjacent to at least one side of the active region AA-DM. Circuits or lines for driving the active region AA-DM may be provided in the peripheral region NAA-DM.

The adhesive member AP may be formed from the resin composition of one or more embodiments. The adhesive member AP may include a polymer derived from the resin composition. The resin composition of one or more embodiments will be described later. The display module DM and the window WP may be bonded through the adhesive member AP. The adhesive member AP of one or more embodiments has a glass transition temperature of about −20° C. or greater and less than about 20° C., and may thus exhibit excellent or suitable adhesive properties without deteriorating adhesion to the window WP and the display module DM even at high temperature and humidity conditions.

The window WP may include a transmission region TA and a bezel region BZA. The transmission region TA may overlap at least a portion of the active region AA-DM of the display module DM. The transmission region TA may be an optically transparent region. The image IM (FIG. 1) may be provided to users through the transmission region TA.

The bezel region BZA may be a region having a relatively lower light transmittance than the transmission region TA. The bezel region BZA may define a shape of the transmission region TA. The bezel region BZA may be adjacent to the transmission region TA and may surround the transmission region TA.

The bezel region BZA may have a set or predetermined color. The bezel region BZA covers the peripheral region NAA-DM of the display module DM, and may thus prevent or reduce the peripheral region NAA-DM from being viewed from the outside. However, the embodiment of the present disclosure is not limited to what is shown, and the bezel region BZA may be provided adjacent to only one side of the transmission region TA, and at least a portion thereof may not be provided.

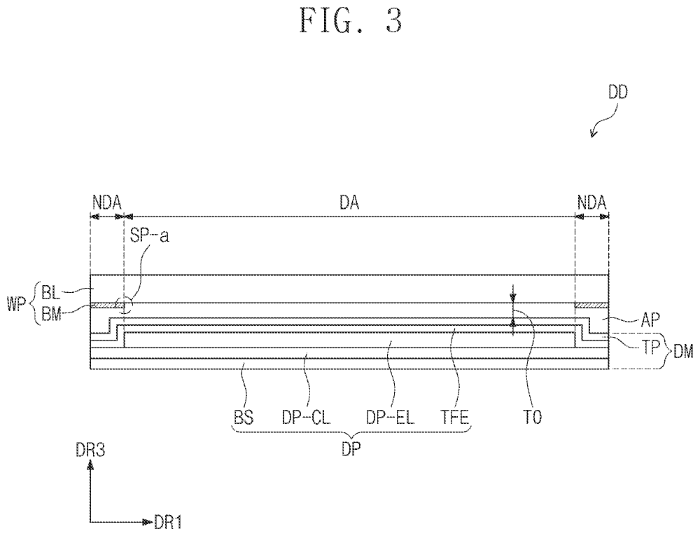

FIG. 3 is a cross-sectional view showing the display module DM, the adhesive member AP, and the window WP of FIG. 2. In some embodiments, FIG. 3 is a cross-sectional view showing a display device DD according to one or more embodiments.

Referring to FIG. 3, the display module DM may include a display panel DP and an input sensing portion TP provided on the display panel DP. The display panel DP may include a base substrate BS, a circuit layer DP-CL provided on the base substrate BS, and a display element layer DP-EL provided on the circuit layer DP-CL, and an encapsulation layer TFE covering the display element layer DP-EL. The adhesive member AP may be provided between the display panel DP and the window WP.

In some embodiments, the components of the display panel DP shown in FIG. 3 and/or the like are an example and the components of the display panel DP are not limited thereto. For example, the display panel DP may include a liquid crystal display element, and in this case, the encapsulation layer TFE may not be provided.

The base substrate BS may provide a base surface on which the circuit layer DP-CL is provided. The base substrate BS may be a flexible substrate that is bendable, foldable, rollable, and/or the like. The base substrate BS may be a glass substrate, a metal substrate, or a polymer substrate. However, the embodiment of the present disclosure is not limited thereto, and the base substrate BS may be an inorganic layer, an organic layer, or an organic-inorganic composite material layer.

The circuit layer DP-CL may include an insulating layer, a semiconductor pattern, a conductive pattern, a signal line, and/or the like. For example, the circuit layer DP-CL may include a switching transistor and a driving transistor for driving a light emitting element of the display element layer DP-EL.

The display element layer DP-EL may include a light emitting element emitting light. For example, the light emitting element may include organic light emitting materials, inorganic light emitting materials, organic-inorganic light emitting materials, quantum dots, quantum rods, micro LEDs, or nano LEDs.

The encapsulation layer TFE may be provided above the display element layer DP-EL. The encapsulation layer TFE may serve to protect the display emitting element layer DP-EL from moisture, oxygen, and/or foreign substances such as dust particles. The encapsulation layer may include at least one inorganic layer. In some embodiments, the encapsulation layer TFE may include at least one organic layer and at least one inorganic layer. For example, the encapsulation layer TFE may include an inorganic layer, an organic layer, and an inorganic layer, which are sequentially stacked.

The input sensing portion TP may be provided on the display panel DP. For example, the input sensing portion TP may be directly provided on the encapsulation layer TFE of the display panel DP. The input sensing portion TP may sense external inputs to convert the inputs into set or predetermined input signals, and provide the input signals to the display panel DP. For example, in the display device DD of one or more embodiments, the input sensing portion TP may be a touch sensing portion detecting a touch. The input sensing portion TP may recognize a user's direct touch, a user's indirect touch, a direct touch of an object, or an indirect touch of an object.

The input sensing portion TP may sense at least any one of a location of a touch or strength (pressure) of a touch applied from the outside. In one or more embodiments, the input sensing portion TP may have one or more suitable structures or be formed of one or more suitable materials, and is not limited to any one embodiment. The input sensing portion TP may include a plurality of sensing electrodes for sensing external inputs. The sensing electrodes may sense external inputs in a capacitive manner. The display panel DP may receive the input signals from the input sensing portion TP and generate images corresponding to the input signals.

The window WP may include a base layer BL and a printing layer BM. the window WP may further include at least one functional layer provided on the base layer BL. For example, the functional layer may be a hard coating layer, an anti-fingerprint coating layer, and/or the like, but the embodiment of the present disclosure is not limited thereto.

The base layer BL may be a glass substrate. In some embodiments, the base layer BL may be a plastic substrate. For example, the base layer BL may be formed of polyimide, polyacrylate, polymethylmethacrylate, polycarbonate, polyethylenenaphthalate, polyvinylidene chloride, polyvinylidene difluoride, polystyrene, ethylene vinylalcohol copolymer, or a combination thereof.

The printing layer BM may be provided on one surface of the base layer BL. The printing layer BM may be provided on a lower surface of the base layer BL adjacent to the display module DM. The printing layer BM may be provided on an edge region of the base layer BL. The printing layer BM may be an ink printing layer. In some embodiments, the printing layer BM may be a layer formed by including a pigment or dye. In the window WP, the bezel region BZA may be a portion in which the printing layer BM is provided.

The adhesive member AP may be provided the window WP. In the window WP, a step SP-a may be present between the base layer BL on which the printing layer BM is not provided and the printing layer BM. The adhesive member AP formed from the resin composition according to one or more embodiments has satisfactory flexibility and high adhesion and may thus be attached to the window WP without lifting at the step SP-a.

The resin composition of one or more embodiments may include a urethane (meth)acrylate oligomer and a monofunctional (meth)acrylate monomer. In some embodiments, the resin composition of one or more embodiments may further include a photo-initiator.

The urethane (meth)acrylate oligomer may include two or more (meth)acryloyl groups. The urethane (meth)acrylate oligomer may include two or more (meth)acryloyl groups per oligomer. The urethane (meth)acrylate oligomer may include two or more (meth)acryloyl groups having a urethane bond per oligomer. For example, the urethane (meth)acrylate oligomer may include 2 to 4 (meth)acryloyl groups per oligomer. Herein, the (meth)acryloyl group indicates an acryloyl group or a methacryloyl group, and the (meth)acryl indicates acryl or methacryl.

The urethane (meth)acrylate oligomer may include aliphatic urethane acrylate, or aromatic urethane acrylate. For example, at a glass transition temperature (Tg) of 0° C. or less, the urethane (meth)acrylate oligomer may include aromatic urethane acrylate. In some embodiments, the urethane (meth)acrylate oligomer may include a urethane acrylate having a polyether skeleton (i.e., molecular structure). The urethane acrylate having a polyether skeleton may be a urethane acrylate having a polyester skeleton, a urethane acrylate having a polycarbonate skeleton, and/or the like, but the embodiment of the present disclosure is not limited thereto.

The resin composition of one or more embodiments may include one or two or more types (kinds) of urethane (meth)acrylate oligomers. For example, the resin composition may include at least one selected from among UV-3700B (urethane acrylate, manufactured by Mitsubishi Chemical Inc.), UV-3300B (urethane acrylate, manufactured by Mitsubishi Chemical Inc.), and/or UN-7700 (urethane acrylate, manufactured by Negami Chemical Industrial Co., Ltd) as the urethane (meth)acrylate oligomer. However, this is presented as an example, and the embodiment of the present disclosure is not limited thereto.

In one or more embodiments, the urethane (meth)acrylate oligomer may have a weight average molecular weight (Mw) of about 10,000 g/mol or greater and less than about 40,000 g/mol. The urethane (meth)acrylate oligomer having a weight average molecular weight of about 10,000 g/mol or greater is included in the resin composition in a state of oligomer having a relatively higher degree of polymerization, and may thus maintain a high degree of polymerization even after photocuring. Accordingly, the adhesive member AP formed from the resin composition of one or more embodiments may exhibit excellent or suitable peeling force.

The resin composition may include the urethane (meth)acrylate oligomer in an amount of about 1 wt % or greater and less than about 10 wt % with respect to 100 wt % of the resin composition. For example, when the resin composition includes two or more types (kinds) of urethane (meth)acrylate oligomers, a total amount of the two or more types (kinds) of urethane (meth)acrylate oligomers included in the resin composition may be about 1 wt % or greater and less than about 10 wt % with respect to 100 wt % of the total resin composition. When the resin composition of one or more embodiments includes the urethane (meth)acrylate oligomer in the above amount range, the resin composition may have a viscosity of about 5 mPa·s or greater and at most (e.g., less than) about 20 mPa·s, at about 30° C. Accordingly, the resin composition of one or more embodiments may be applied in a substantially uniform amount and at a substantially uniform thickness on the display module DM or the window WP through inkjet printing, and may thus form the adhesive member AP.

In contrast, when the resin composition of one or more embodiments includes the urethane (meth)acrylate oligomer in an amount of less than about 1 wt %, the resin composition has too low viscosity and thus is not applied at a substantially uniform thickness and/or in a substantially uniform amount during a process, and accordingly, the adhesive member AP may have uneven thickness. In some embodiments, when the resin composition of one or more embodiments includes the urethane (meth)acrylate oligomer in an amount of about 10 wt % or greater, the resin composition has excessively high viscosity, and is likely to cause ejection defects and nozzle clogging during a process.

In one or more embodiments, the resin composition may include a monofunctional (meth)acrylate monomer. The monofunctional (meth)acrylate monomer may be an acrylate monomer or a methacrylate monomer containing one acryloyl group or one methacryloyl group. The monofunctional (meth)acrylate monomer may include a plurality of different monomers. For example, in the resin composition of one or more embodiments, the monofunctional (meth)acrylate monomer may include at least one monofunctional acrylate monomer or at least one monofunctional methacrylate monomer.

In the resin composition of one or more embodiments, the monofunctional (meth)acrylate monomer may include a hydroxy group-containing (meth)acrylate and an alicyclic (meth)acrylate. In some embodiments, the monofunctional (meth)acrylate monomer may further include at least one selected from among an alkyl (meth)acrylate and/or a heteroalicyclic (meth)acrylate.

The hydroxy group-containing (meth)acrylate may be a (meth)acrylate having a hydroxy group. The hydroxy (meth)acrylate may be a C1 to C10 (meth)acrylate having at least one hydroxy group. For example, the hydroxy (meth)acrylate may include at least one selected from among 2-hydroxyethyl (meth)acrylate, 2-hydroxypropyl (meth)acrylate, 3-hydroxypropyl (meth)acrylate, 2-hydroxybutyl (meth)acrylate, 4-hydroxybutyl (meth)acrylate, 6-hydroxyhexyl (meth)acrylate, 8-hydroxyoctyl (meth)acrylate, and 10-hydroxydecyl (meth)acrylate.

In one or more embodiments, the resin composition may include the hydroxy group-containing (meth)acrylate in an amount of about 5 mol % or greater and less than about 20 mol % with respect to 100 mol % of the total resin composition. For example, the hydroxy group-containing (meth)acrylate may have a concentration (mol %) of about 5 mol % or greater and less than about 20 mol %.

When the resin composition of one or more embodiments includes the hydroxy group-containing (meth)acrylate in the concentration described herein, the adhesive member AP formed from the resin composition of one or more embodiments may have excellent or suitable adhesion and does not have cloudiness at high temperature and humidity conditions. In some embodiments, when the resin composition of one or more embodiments includes the hydroxy group-containing (meth)acrylate in an amount of less than about 5 mol %, the window WP may have reduced adhesiveness, and may thus have degradation in 180° peel force. In some embodiments, when the resin composition includes the hydroxy group-containing (meth)acrylate in an amount of about 20 mol % or greater, the adhesive member AP may have greater moisture absorption properties at high temperature and humidity conditions, and may thus have a high haze change rate. In this case, cloudiness may not be caused in the adhesive member AP, and the display device DD may thus have reduced viewability.

The alicyclic (meth)acrylate is a (meth)acrylate containing an alicyclic group and may have a glass transition temperature of about 80° C. or greater. The alicyclic (meth)acrylate may be a (meth)acrylate having a ring composed only of carbon having a monocyclic ring or a polycyclic ring having 3 to 10 carbon atoms. For example, the alicyclic (meth)acrylate having a glass transition temperature of about 80° C. or greater may include at least one selected from among isobornyl (meth)acrylate, dicyclopentanyl (meth)acrylate, and/or dicyclopentenyloxyethyl (meth)acrylate.

In one or more embodiments, the resin composition may include the alicyclic (meth)acrylate in an amount of about 10 wt % or greater and about 40 wt % or less with respect to 100 wt % of the total resin composition. When the resin composition of one or more embodiments includes the alicyclic (meth)acrylate in the amount range of about 10 wt % or greater and about 40 wt % or less, the adhesive member AP formed from the resin composition of one or more embodiments may exhibit excellent or suitable adhesion even when exposed to high temperature and humidity conditions.

The alkyl (meth)acrylate may be a (meth)acrylate having an alkyl group. The alkyl (meth)acrylate may be a (meth)acrylate containing an unsubstituted alkyl group having 1 to 10 carbon atoms. For example, the alkyl (meth)acrylate may include at least one selected from among methyl (meth)acrylate, ethyl (meth)acrylate, propyl (meth)acrylate, n-butyl (meth)acrylate, t-butyl (meth)acrylate, iso-butyl (meth)acrylate, pentyl (meth)acrylate, hexyl (meth)acrylate, heptyl (meth)acrylate, octyl (meth)acrylate, nonyl (meth)acrylate, and/or iso-decyl (meth).

The heteroalicyclic (meth)acrylate may be a (meth)acrylate containing a heteroalicyclic group. The heteroalicyclic (meth)acrylate may be a (meth)acrylate containing hetero elements such as oxygen atoms, sulfur atoms, and nitrogen atoms among the elements constituting a ring and having a monocyclic ring or polycyclic ring having 4 to 10 carbon atoms. For example, the heteroalicyclic (meth)acrylate may include tetrahydrofurfuryl (meth)acrylate and/or the like. However, this is presented as an example, and the embodiment of the present disclosure is not limited thereto.

In one or more embodiments, the hydroxy group-containing (meth)acrylate, the alicyclic (meth)acrylate, the alkyl (meth)acrylate, and the heteroalicyclic (meth)acrylate may each have a weight average molecular weight of about 150 g/mol to about 300 g/mol. When each of the monomers included in the monofunctional (meth)acrylate monomer has a weight average molecular weight in the above range, the adhesive member AP formed from the resin composition of one or more embodiments may provide excellent or suitable adhesion at high temperature and humidity conditions. When the monofunctional (meth)acrylate monomer has a weight average molecular weight of greater than about 300 g/mol, the adhesive member may have reduced adhesion, and the resin composition may have greater viscosity to cause ejection defects during an inkjet process. When the monofunctional (meth)acrylate monomer has a weight average molecular weight of less than about 150 g/mol, a cured product may have reduced molecular weight to cause cloudiness and resin degradation at high temperature and humidity conditions.

Herein, the amount of the monofunctional (meth)acrylate monomer included in the resin composition is not particularly limited, but, for example, the resin composition may include the monofunctional (meth)acrylate monomer in an amount of about 75 wt % to about 99 wt % with respect to 100 wt % of the total resin composition. When the resin composition includes the monofunctional (meth)acrylate monomer in the above amount range, the adhesive member AP of one or more embodiments may have a glass transition temperature of about −20° C. or greater and about 20° C. or less. Accordingly, the adhesive member AP may provide excellent or suitable adhesion without causing peeling even at high temperature and humidity conditions.

The resin composition RC of one or more embodiments may include a photo-initiator. The photo-initiators may include a radical polymerization initiator. The resin composition may include one or two or more types (kinds) of photo-initiators. When the resin composition includes a plurality of photo-initiators, each of the photo-initiators may be activated by UV light having different central wavelengths.

For example, the photo-initiator may include at least one selected from among 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, and/or 2-hydroxy-1-{4-[4-(2-hydroxy-2-methyl-propionyl)-benzyl]-phenyl}-2-methylpropan-1-one.

In some embodiments, the photo-initiator may include at least one selected from among 2-methyl-1[4-(methylthio)phenyl]-2-morpholinopropan-1-one, 2-benzyl-2-dimethylamino-1-(4-morpholinophenyl)-1-butanone, 2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenylbis(2,4,6-trimethylbenzoyl)phosphine oxide, [1-(4-phenylsulfanylbenzoyl) heptylideneamino]benzoate, [1-[9-ethyl-6-(2-methylbenzoyl)carbazol-3-yl]ethylideneamino]acetate), and/or bis(2,4-cyclopentadienyl)bis[2,6-difluoro-3-(1-pyrryl)phenyl]titanium(IV). In some embodiments, the resin composition RC may include at least one selected from among Omnirad 819 (from IGM Resins) and/or Omnirad 184 (from IGM Resins), as a photo-initiator. The Omnirad 819 (from IGM Resins) and the Omnirad 184 (from IGM Resins) are radical polymerization initiators.

The resin composition of one or more embodiments may include an organic solvent in an amount of about 1 wt % with respect to 100 wt % of the total resin composition. For example, the resin composition may include substantially no organic solvent. For example, the resin composition of one or more embodiments may be a non-solvent resin composition (i.e., solvent-free resin composition). When the adhesive member AP is formed utilizing the non-solvent resin composition, a process for drying the organic solvent may not be provided from processes. For example, an additional drying process is omitted after the non-solvent resin composition is applied onto the display module DM or the window WP, and a long-term roll-to-roll process may thus be available to improve production efficiency and product quality.

The resin composition of one or more embodiments may have a viscosity of about 5 mPa·s or greater and about 20 mPa·s or less, at 30° C. The viscosity is a value measured in accordance with Japanese Industrial Standard (JIS) K 2283. According to one or more embodiments of the present disclosure, for a resin composition having a viscosity of less than about 5 mPa·s at a temperature of 30° C. as measured by JIS K 2283, sagging may be caused when the resin composition is provided. For example, sagging may occur when the resin composition may not be applied in a substantially uniform amount and/or at a substantially uniform thickness. The “sagging” indicates a phenomenon in which a resin composition flows out of a desired or suitable member. A resin composition having a viscosity of greater than about 20 mPa·s at 30° C. as measured by JIS K 2283 is not easy for ejection, and clogging may be caused in a nozzle NZ.

The adhesive member AP of one or more embodiments may be a cured product formed by providing the resin composition of one or more embodiments on one surface of the window WP or one surface of the display module DM, and then irradiating the resin composition provided on one surface of the window WP or one surface of the display module DM with UV light. However, the embodiment of the present disclosure is not limited thereto. For example, the adhesive member AP may be provided by UV-curing the resin composition of one or more embodiments to form an adhesive member AP, laminating one surface of the adhesive member AP in a cured state in the form of an adhesive film on one surface of the window WP or one surface of the display module DM, and attaching one surface of the window WP or one surface of the display module DM, which is unattached, to the other surface of the adhesive member AP.

In one or more embodiments, the adhesive member AP may have a thickness TO (FIG. 3) of about 50 micrometer (μm) to about 200 μm. For example, the adhesive member AP may have a thickness TO of about 100 μm to about 200 μm. In one or more embodiments, the adhesive member AP may have a thickness TO of about 200 μm. However, this is presented as an example, and the thickness TO of the adhesive member AP is not limited thereto.

The adhesive member AP may have a haze of about 1% or less at a thickness of about 200 μm or less. For example, the adhesive member AP may have a haze of about 0.1% or greater and about 1% or less at a thickness of about 50 μm to about 200 μm. The adhesive member AP having a haze value in the above range exhibits excellent or suitable transparency and may thus improve viewability when applied to the display device DD. Herein, the haze value is a haze value for a cured product formed by curing the resin composition of one or more embodiments, and may be measured in accordance with JIS K 7136:2000. In this case, the cured product may correspond to the adhesive member AP.

In one or more embodiments, the cured product, that is, the adhesive member AP may have a haze change rate of about 2% or less in Equation 1.

$$Haze change rate ( \% ) = H 2 ‐ H 1 \qquad [ Equation 1 ]$$

In Equation 1 herein, H1 may be a haze value (unit: %) immediately (e.g., right) after forming the cured product (i.e., the adhesive member AP). H2 may be a haze value (unit: %) when (e.g., after) the cured product (i.e., the adhesive member AP) is exposed for about 72 hours at a temperature of about 85° C. and a humidity of about 85%.

The adhesive member AP formed from the resin composition of one or more embodiments may have a moisture absorption rate of about 2% or less when exposed to high temperature and humidity conditions for about 72 hours. Herein, the high temperature may be a temperature of about 85° C., and the high humidity may be about 85% RH. For example, the adhesive member AP may have a moisture absorption rate of about 0.1% or greater and about 2% or less, or about 0.6% to about 1.1% at high temperature and humidity conditions. The moisture absorption rate may be obtained as a ratio to the weight before exposure for about 72 hours at a temperature of about 85° C. and a humidity of about 85% RH. When the adhesive member AP has a moisture absorption rate of the above range or greater, that is, greater than about 2%, the adhesive member AP has a greater haze value at high temperature and humidity conditions, and the display device DD may thus have reduced viewability.

In one or more embodiments, the adhesive member AP may have a 180º peel force of about 400 gf/25 mm or greater with respect to a glass substrate and/or a polymer substrate. The adhesive member AP may exhibit excellent or suitable 180° peel force at high temperature and humidity conditions. For example, the adhesive member AP may have a 180° peel force of about 400 gf/25 mm or greater with respect to a glass substrate and/or a polymer substrate when exposed for about 72 hours at a temperature of about 85° C. and a humidity of about 85%.

The adhesive member AP having a 180° peel force of at most about 400 gf/25 mm with respect to a glass substrate and/or a polymer substrate at high temperature and humidity conditions has low adhesive reliability, and when exposed to high temperature and humidity conditions for a long period of time, the adhesive member AP may be peeled off from the display module DM and/or the window WP. In contrast, the adhesive member AP of one or more embodiments having a 180° peel force of greater than about 400 gf/25 mm with respect to a glass substrate and/or a polymer substrate may exhibit excellent or suitable adhesive reliability at high temperature and humidity conditions. Accordingly, the display device DD including the adhesive member AP according to one or more embodiments may exhibit excellent or suitable durability.

In one or more embodiments, the adhesive member AP may have a glass transition temperature (Tg) of about −20° C. or greater and about 20° C. or less. The adhesive member AP having a glass transition temperature in the above range may exhibit high adhesion to the window WP even when exposed to high temperature and humidity conditions. In some embodiments, when the adhesive member AP has a glass transition temperature (Tg) of at most (e.g., less than) about −20° C., the adhesive member AP, which is a cured product of the resin composition, softens due to reduced resistance in a moist heat environment, and may thus have reduced adhesion. In some embodiments, when the adhesive member AP has a glass transition temperature (Tg) of greater than about 20° C., the adhesion to the window WP is reduced, and moisture penetrates an interface between the window WP and the adhesive member AP in a moist heat environment, and accordingly, the adhesive member AP may have reduced adhesive strength.

The display device DD of one or more embodiments may be formed utilizing a method for manufacturing a display device of one or more embodiments. In the method for manufacturing a display device of one or more embodiments, the adhesive member AP may be formed from the resin composition of embodiment described herein. The method of manufacturing a display device of one or more embodiments may include providing a resin composition onto a first substrate, primary-curing the resin composition to form a preliminary adhesive member, and disposing a second substrate on the preliminary adhesive member and then secondary-curing the second substrate to form an adhesive member. In one or more embodiments, any one of the first substrate or the second substrate may be the display module DM (FIG. 3), and the other one other than the display module DM (FIG. 3) may be a window WP (FIG. 3).

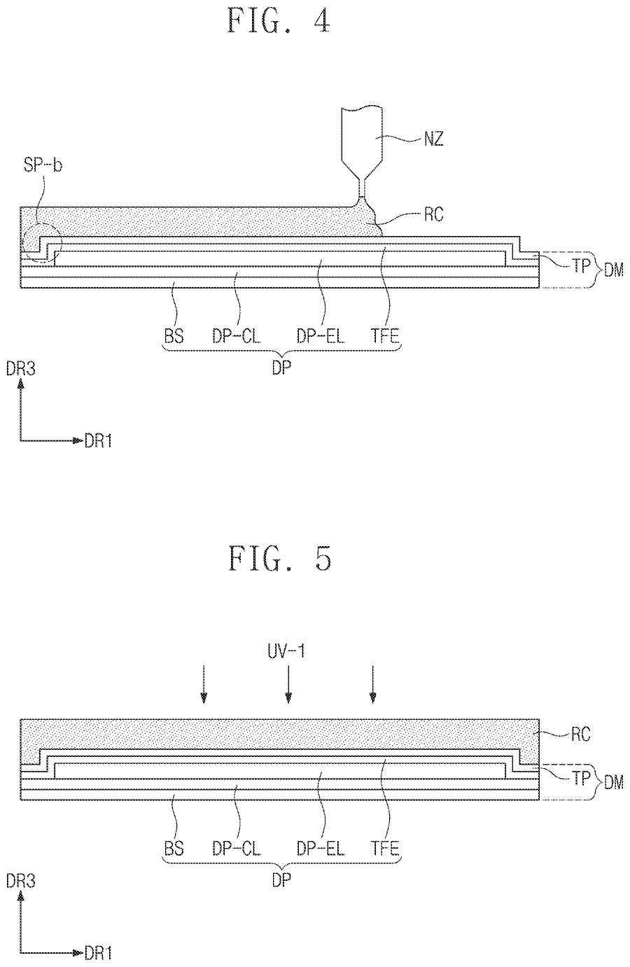

FIGS. 4 to 6 each schematically show a method for manufacturing a display device of one or more embodiments. Hereinafter, in descriptions of the method for manufacturing a display device of one or more embodiments with reference to FIGS. 4 to 6, content (e.g., features) overlapping the one described with reference to FIGS. 1 to 3 will not be described again, and the differences will be mainly described.

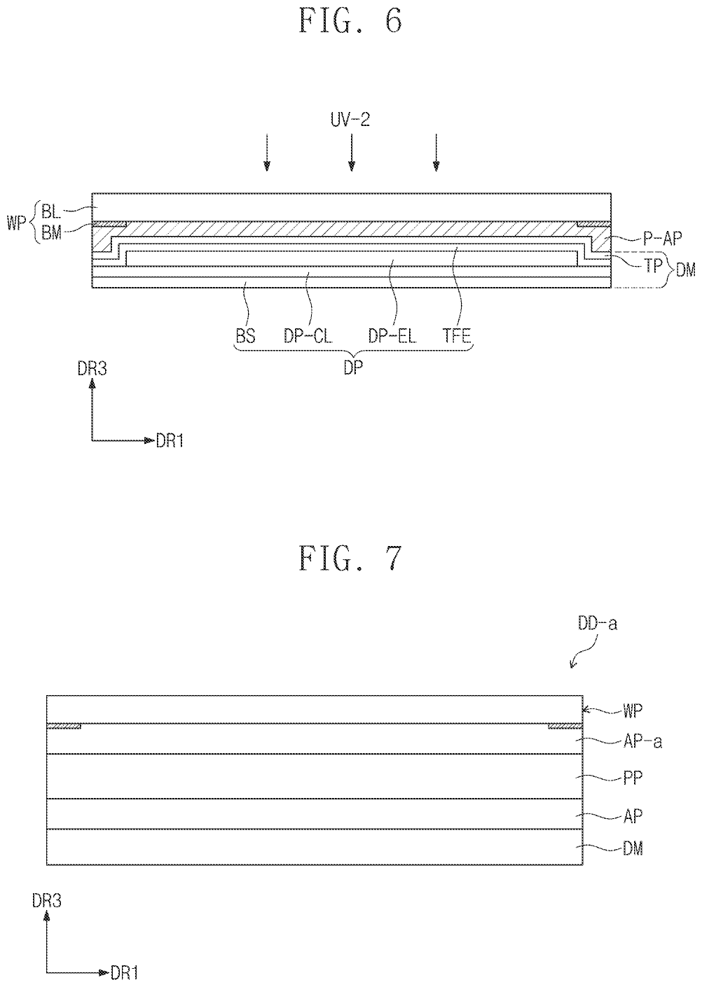

FIG. 4 shows a step of providing a resin composition to form an adhesive member on a first substrate. Referring to FIG. 4, the resin composition RC may be provided on the first substrate through a nozzle NZ. The first substrate is a member provided with the resin composition RC, and in FIG. 4, the resin composition RC is provided on one surface of the display module DM. In this case, the second substrate may be a window WP (FIG. 6).

In one or more embodiments, the resin composition RC may be provided on one surface of the window WP. A preliminary adhesive member P-AP may be formed from the resin composition RC provided on one surface of the window WP. In this case, the second substrate may be the display module DM.

In some embodiments, the resin composition RC may be provided on a separate substrate (e.g., a carrier substrate). In the case of forming the preliminary adhesive member P-AP by providing the resin composition RC on a separate substrate, on the separate substrate, a release treatment may be performed on a surface on which the resin composition RC is applied.

The resin composition RC may be provided through inkjet printing or dispensing. The resin composition RC may be provided at a temperature of about 30° C. In the case of providing the resin composition at a temperature of less than about 30° C., keeping the temperature stable may not be easy, and the temperature change reduces manufacturing reliability. When the resin composition is provided at a temperature greater than about 30° C., the volatility of monomers (monofunctional monomers, and/or the like) included in the resin composition increases. Accordingly, when the resin composition RC is provided at a temperature greater than about 30° C., the resin composition RC may be hardly ejected from the nozzle NZ, making it difficult to form the adhesive member AP. In contrast, when the resin composition RC is provided at the temperature of about 30° C., the resin composition RC is well ejected from the nozzle NZ, making it easy to form the adhesive member AP.

As described herein, the resin composition RC of one or more embodiments has a viscosity of about 5 mPa·s or greater and at most (e.g., less than) about 20 mPa·s, at about 30° C., and may thus be easily ejected from the nozzle NZ, and/or the like, and may be provided to maintain a thin, regular coating thickness.

The resin composition RC may be cured by light. FIG. 5 shows a step of providing a first light UV-1 to the resin composition RC applied onto the first substrate to form the preliminary adhesive member P-AP (FIG. 6). FIG. 6 shows a step of providing the window WP on the preliminary adhesive member P-AP and providing a second light UV-2 to the preliminary adhesive member P-AP. When the preliminary adhesive member P-AP is irradiated with the second light UV-2 and cured, the adhesive member AP of one or more embodiments (FIG. 3) may be formed. The second light UV-2 may be transmitted through the window WP and provided to the preliminary adhesive member P-AP.

The first light UV-1 and the second light UV-2 may be light in the range of ultraviolet electromagnetic radiation (UV). A total amount of the second light UV-2 may be greater than a total amount of the first light UV-1. For example, the first light UV-1 may have a total amount of about 200 mJ/cm² to about 1000 mJ/cm². The second light UV-2 may have a total amount of about 3500 mJ/cm² to about 4500 mJ/cm². However, this is presented as an example, and the total amount of the first light UV-1 and the total amount of the second light UV-2 are not limited thereto.

As described herein, the adhesive member AP formed from the resin composition RC of one or more embodiments may exhibit a glass transition temperature of about −20° C. or greater and at most (e.g., less than) about 20° C., a haze of at most (e.g., less than) about 1% at a thickness of about 200 μm or less, and a moisture absorption rate of at most (e.g., less than) about 20% when exposed for about 72 hours at a temperature of about 85° C. and a humidity of about 85%. Accordingly, the adhesive member AP (FIG. 3) formed from the resin composition RC of one or more embodiments has excellent or suitable adhesion and transparency even at high temperature and humidity conditions, and may thus provide excellent or suitable durability and improved display quality when applied to the display device DD.

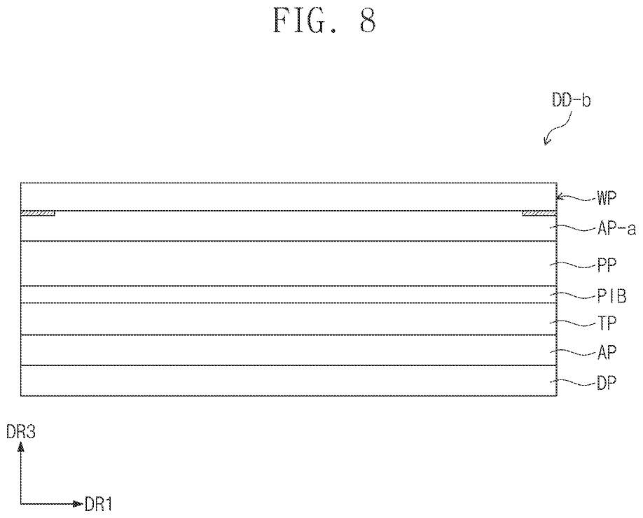

FIG. 7 is a cross-sectional view showing a display device according to one or more embodiments. Hereinafter, in the description of the display device shown in FIG. 7, content (e.g., features) overlapping the one described with reference to FIGS. 1 to 6 will not be described again, and differences will be mainly described.

A display device DD-a shown in FIG. 7 may further include a light control layer PP and an optical adhesive layer AP-a, compared to the display device DD described with reference to FIGS. 2 and 3. The display device DD-a of one or more embodiments may further include a light control layer PP provided between the adhesive member AP and the window WP, and an optical adhesive layer AP-a provided between the light control layer PP and the window WP.

The light control layer PP may be provided on the display panel DP to control reflected light in the display panel DP due to external light. The light control layer PP may include, for example, a polarizing plate or a color filter layer.

The optical adhesive layer AP-a may be an optically clear adhesive resin layer (OCR). The optical adhesive layer AP-a may be formed from the resin composition according to one or more embodiments described herein. In some embodiments, the optical adhesive layer AP-a may be an optically clear adhesive film (OCA).

The optical adhesive layer AP-a formed from the resin composition of one or more embodiments may have a 180° peel force of about 400 gf/25 mm or greater with respect to a glass substrate or a polymer substrate even when exposed to high temperature and humidity conditions for about 72 hours. Accordingly, the optical adhesive layer AP-a of one or more embodiments may exhibit high adhesion. The display device DD-a of one or more embodiments includes the optical adhesive layer AP-a and the adhesive member AP formed from the resin composition of one or more embodiments. The optical adhesive layer AP-a and the adhesive member AP have high adhesion, and the display device DD-a does not have lifting at an interface between the optical adhesive layer AP-a and the adhesive member AP at high temperature and humidity conditions, thereby exhibiting excellent or suitable durability.

FIG. 8 is a cross-sectional view showing a display device according to one or more embodiments. Hereinafter, in the description of the display device of one or more embodiments shown in FIG. 8, content (e.g., features) overlapping the one described with reference to FIGS. 1 to 7 will not be described again, and differences will be mainly described.

A display device DD-b of one or more embodiments shown in FIG. 8 may further include a light control layer PP, an optical adhesive layer AP-a, and an interlayer adhesive layer PIB, compared to the display device DD described with reference to FIGS. 2 and 3. As the display device DD-a of one or more embodiments shown in FIG. 7, the display device DD-b of one or more embodiments shown in FIG. 8 may further include a light control layer PP provided between the adhesive member AP and the window WP, and an optical adhesive layer AP-a provided between the light control layer PP and the window WP.

In the display device DD-b of one or more embodiments, the adhesive member AP may be provided between the display panel DP and the input sensing portion TP. For example, the input sensing portion TP may not be directly provided on the display panel DP, and the display panel DP and the input sensing portion TP may be bonded through the adhesive member AP. For example, the adhesive member AP may be provided between the encapsulation layer TFE (FIG. 3) of the display panel DP and the input sensing portion TP.

The interlayer adhesive layer PIB may be provided at the light control layer PP. The interlayer adhesive layer PIB may be provided between the input sensing portion TP and the light control layer PP and may be formed of an adhesive material having excellent or suitable moisture permeation prevention properties. For example, the interlayer adhesive layer PIB may be formed including polyisobutylene. The interlayer adhesive layer PIB may be provided on the input sensing portion TP to prevent or reduce corrosion of sensing electrodes of the input sensing portion TP. The display device DD-b of one or more embodiments includes an optical adhesive layer AP-a and an adhesive member AP formed of the resin composition RC according to one or more embodiments. Accordingly, the display device DD-b of one or more embodiments may exhibit excellent or suitable durability and improved display quality.

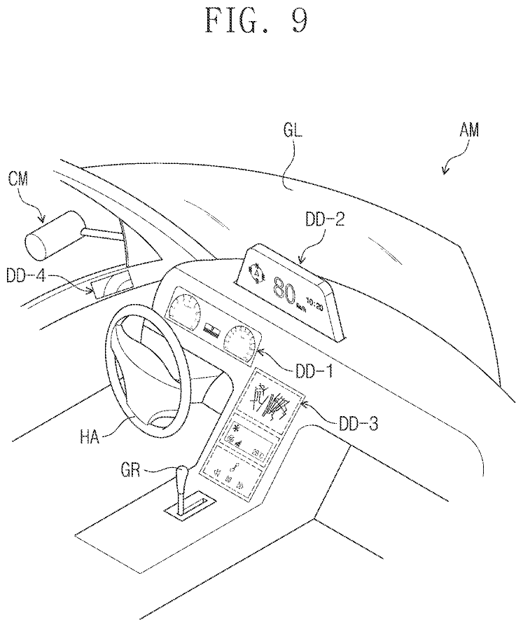

FIG. 9 is a view showing a vehicle AM in which first to fourth display devices DD-1, DD-2, DD-3, and DD-4 are provided. At least one selected from among the first to fourth display devices DD-1, DD-2, DD-3, and DD-4 may have the same components as any one of the display devices DD, DD-a, and DD-b of one or more embodiments described with reference to FIGS. 1 to 3, 7, and 8.

FIG. 9 shows a car as the vehicle AM, but this is presented as an example, and the first to fourth display devices DD-1, DD-2, DD-3, and DD-4 may be provided on other refers to of transportation, such as bicycles, motorcycles, trains, ships, and airplanes. In some embodiments, at least one selected from among the first to fourth display devices DD-1, DD-2, DD-3, and DD-4 including the same components as any one of the display devices DD, DD-a, and DD-b of one or more embodiments may be adopted for other electronic devices without departing from the present disclosure.

At least one selected from among the first to fourth display devices DD-1, DD-2, DD-3, and DD-4 may include the adhesive member AP of one or more embodiments. The adhesive member AP of one or more embodiments may have a glass transition temperature of about −20° C. or greater and about 20° C. or less, and may have a haze of about 1% or less at a thickness of about 200 μm or less. In some embodiments, the adhesive member AP of one or more embodiments may have a moisture absorption rate of about 2% or less even when exposed to a temperature of about 85° C. and a humidity of about 85% for about 72 hours, and may have a 180º peel force of about 400 gf/25 mm or greater with respect to a glass substrate and/or a polymer substrate. Accordingly, at least one selected from among the first to fourth display devices DD-1, DD-2, DD-3, and DD-4 including the adhesive member AP of one or more embodiments has excellent or suitable durability and excellent or suitable display quality.

Referring to FIG. 9, the vehicle AM may include a wheel HA and a gear GR for operating the vehicle AM, and have a front window GL provided to face a driver.

The first display device DD-1 may be provided in a first region overlapping the wheel HA. For example, the first display device DD-1 may be a digital cluster displaying first information of the vehicle AM. The first information may include a first scale indicating driving speed of the vehicle AM, a second scale indicating engine revolutions (i.e., revolutions per minute (RPM)), and an image indicating fuel gauge, and/or the like. The first scale and the second scale may be displayed as digital images.

The second display device DD-2 may be provided in a second region facing a driver seat and overlapping the front window GL. The driver seat may be a seat in which the wheel HA is provided. For example, the second display device DD-2 may be a head up display (HUD) displaying second information of the vehicle AM. The second display device DD-2 may be optically transparent. The second information includes digital numbers indicating driving speed of the vehicle AM and may further include information such as current time. Unlike what is shown, the second information of the second display device DD-2 may be projected and displayed on the front window GL.

The third display device DD-3 may be provided in a third region adjacent to the gear GR. For example, the third display device DD-3 may be a center information display CID for a vehicle AM, which is provided between a driver seat and a front passenger seat and displays third information. The passenger seat may be a seat spaced apart from the driver seat with the gear GR therebetween. The third information may include information about road conditions (e.g., navigation information), music or radio play, dynamic video (or image) play, temperature inside the vehicle AM, and/or the like.

The fourth display device DD-4 may be provided in a fourth region spaced apart from the wheel HA and the gear GR and adjacent to a side of the vehicle AM. For example, the fourth display device DD-4 may be a digital side mirror displaying fourth information. The fourth display device DD-4 may display images of conditions outside the vehicle AM, which are taken by a camera module CM provided outside the vehicle AM. The fourth information may include images of conditions outside the vehicle AM.

The first to fourth information described herein are presented as an example, and the first to fourth display devices DD-1, DD-2, DD-3, and DD-4 may further display information about inside or outside a vehicle. The first to fourth information may include different information. However, the embodiment of the present disclosure is not limited thereto, and some of the first to fourth information may include the same information.

In the specification, the x-axis, y-axis, and z-axis are not limited to three axes in an orthogonal coordinate system, and may be interpreted in a broad sense including these axes. For example, the x-axis, y-axis, and z-axis may refer to those orthogonal to each other, or may refer to those in different directions that are not orthogonal to each other.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0”, “at least 1.0 and at most 10.0”, etc., includes all subranges having a minimum value equal to or greater than 1.0 and a maximum value equal to or less than 10.0, such as, for example, “2.4 to 7.6” or “at least 2.4 and at most 7.6”. Applicant therefore reserves the right to amend this specification, including the claims, to expressly recite any sub-range subsumed within the ranges expressly recited herein.

The display device and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the display device may be formed on one integrated circuit (IC) chip or on separate IC chips. Further, the various components of the display device may be implemented on a flexible printed circuit film, a tape carrier package (TCP), a printed circuit board (PCB), or formed on one substrate. Further, the various components of the display device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinafter, with reference to Examples and Comparative Examples, an adhesive member formed from the resin composition according to one or more embodiments of the present disclosure, and a display device will be specifically described. In some embodiments, Examples are shown only for the understanding of the present disclosure, and the scope of the present disclosure is not limited thereto.

### EXAMPLES

### 1. Preparation of Resin Composition

The resin compositions of Examples 1-5 (EX1-EX5) and Comparative Examples 1-6 (CE1-CE6) were prepared at the blending ratios listed in Tables 1 and 2, respectively. Materials disclosed in Tables 1 and 2 were provided in heat-resistant light-shielding containers in respective weight ratios. Thereafter, the compositions were stirred at 1000 rpm for 30 minutes utilizing a revolution and rotation agitation defoaming device (manufactured by SHASHIN KAGAKU CO., LTD.) so that the compositions were evenly mixed to prepare resin compositions of Examples 1-5 (EX1-EX5) and Comparative Examples 1-6 (CE1-CE6).

TABLE 1

| | | Molecular | Tg | | | | | |
|---|---|---|---|---|---|---|---|---|
| Material | | weight | (° C.) | EX1 | EX2 | EX3 | EX4 | EX5 |
| Urethane | UV-3700B | 38000 | −6 | 1 | 4 | | 4 | 4 |
| (meth)acrylate | Urethane | 13000 | −30 | | 4 | 3 | 4 | 4 |
| oligomer | (meth)acrylate | | | | | | | |
| | oligomer | | | | | | | |
| | UV-3300B | | | | | | | |
| | Urethane | 20000 | −41 | | | 6 | | |
| | (meth)acrylate | | | | | | | |
| | oligomer | | | | | | | |
| | UN-7700 | | | | | | | |
| | Urethane | 35000 | | | | | | |
| | (meth)acrylate | | | | | | | |
| | oligomer | | | | | | | |
| | UF-C051 | | | | | | | |
| Oligomer | TEAI-1000 | 2000 | | | | | | |
| Monofunctional | IDAA | 212 | −62 | | 30 | 30 | 15 | 40 |
| (meth)acrylate | Monofunctional | 208 | 97 | 20 | 30 | 33 | 10 | |
| monomer | (meth)acrylate | | | | | | | |
| | monomer IBXA | | | | | | | |
| | Monofunctional | 206 | 120 | | | | | 20 |
| | (meth)acrylate | | | | | | | |
| | monomer | | | | | | | |
| | FA-513AS | | | | | | | |
| | Monofunctional | 184 | −80 | 47 | | | 30 | |
| | (meth)acrylate | | | | | | | |
| | monomer 2-EHA | | | | | | | |
| | Monofunctional | 156 | −12 | 20 | 20 | 20 | 20 | 20 |
| | (meth)acrylate | | | | | | | |
| | monomer THF-A | | | | | | | |
| | Monofunctional | 200 | −7 | | | | | |
| | (meth)acrylate | | | | | | | |
| | monomer Medol-10 | | | | | | | |
| Hydroxy | 4-HBA | 144 | −32 | 10 | 10 | | 15 | 10 |
| group- | Hydroxy group- | 228 | −55 | | | 6 | | |
| containing | containing | | | | | | | |
| (meth)acrylate | (meth)acrylic | | | | | | | |
| | monomer SYA004 | | | | | | | |
| | Hydroxy group- | 116 | −15 | | | | | |
| | containing | | | | | | | |
| | (meth)acrylic | | | | | | | |
| | monomer HEA | | | | | | | |
| Photo- | Omnirad 819 | 418 | — | 2 | 2 | 1 | 1 | 2 |
| initiator | Omnirad 184 | 204 | — | | | 1 | 1 | |

TABLE 2

| | | Molecular | Tg | | | | | | |
|---|---|---|---|---|---|---|---|---|---|
| Material | | weight | (° C.) | CE1 | CE2 | CE3 | CE4 | CE5 | CE6 |
| Urethane | UV-3700B | 38000 | −6 | 6 | 4 | 4 | 4 | 4 | |
| (meth)acrylate | Urethane | 13000 | −30 | 6 | 4 | 4 | 4 | 4 | |
| oligomer | (meth)acrylate | | | | | | | | |
| | oligomer | | | | | | | | |
| | UV-3300B | | | | | | | | |
| | Urethane | 20000 | −41 | | | | | | |
| | (meth)acrylate | | | | | | | | |
| | oligomer | | | | | | | | |
| | UN-7700 | | | | | | | | |
| | Urethane | 35000 | | | | | | | 1 |
| | (meth)acrylate | | | | | | | | |
| | oligomer | | | | | | | | |
| | UF-C051 | | | | | | | | |
| Oligomer | TEAI-1000 | 2000 | | | | | | | 5 |
| Monofunctional | IDAA | 212 | −62 | 36 | 40 | 47 | 20 | 40 | 67 |
| (meth)acrylate | Monofunctional | 208 | 197 | 20 | 15 | 20 | 35 | | |
| monomer | (meth)acrylate | | | | | | | | |
| | monomer | | | | | | | | |
| | IBXA | | | | | | | | |
| | Monofunctional | 206 | 120 | | | | | | |
| | (meth)acrylate | | | | | | | | |
| | monomer | | | | | | | | |
| | FA-513AS | | | | | | | | |
| | Monofunctional | 184 | −80 | | | | | 20 | |
| | (meth)acrylate | | | | | | | | |
| | monomer | | | | | | | | |
| | 2-EHA | | | | | | | | |
| | Monofunctional | 156 | −12 | 20 | 20 | 20 | 20 | 20 | |
| | (meth)acrylate | | | | | | | | |
| | monomer | | | | | | | | |
| | THF-A | | | | | | | | |
| | Monofunctional | 200 | −7 | | | | | | 15 |
| | (meth)acrylate | | | | | | | | |
| | monomer | | | | | | | | |
| | Medol-10 | | | | | | | | |
| Hydroxy group- | 4-HBA | 144 | −32 | 10 | 15 | 3 | | | |
| containing | Hydroxy group- | | | | | | | | |
| (meth)acrylate | containing | 228 | −55 | | | | 15 | 10 | |
| | (meth)acrylic | | | | | | | | |
| | monomer | | | | | | | | |
| | SYA004 | | | | | | | | |
| | Hydroxy group- | 116 | −15 | | | | | | 10 |
| | containing | | | | | | | | |
| | (meth)acrylic | | | | | | | | |
| | monomer | | | | | | | | |
| | HEA | | | | | | | | |
| Photo- | Omnirad 819 | 418 | — | 2 | 2 | 2 | 1 | 1 | 2 |
| initiator | Omnirad 184 | 204 | — | | | | 1 | 1 | |

Data on materials in Tables 1 and 2

UV-3700B: Urethane acrylate (manufactured by Mitsubishi Chemical Inc.)

UV-3300B: Urethane acrylate (manufactured by Mitsubishi Chemical Inc.)

UN-7700: Urethane acrylate (manufactured by Negami Chemical Industrial Co., Ltd)

UF-C051: Urethane acrylate (manufactured by Kyoeisha Chemical Co., Ltd)

TEAI-1000: Polybutadiene compound having a radical curable group (manufactured by Nippon Soda Co., Ltd.)

IDAA: Iso-decyl acrylate (manufactured by Osaka Organic Chemical Industry Ltd)

IBXA: Isobornyl acrylate (manufactured by Osaka Organic Chemical Industry

### Ltd)

FA-513AS: dicyclopentanyl acrylate (manufactured by Showa Denko Materials) 2-EHA: 2-ethylhexyl acrylate (manufactured by TOAGOSEI Corporation)

THF-A: Tetrahydrofurfuryl acrylate (manufactured by Kyoeisha Chemical Co., Ltd)

Medol-10: (2-methyl-2-ethyl-1,3-dioxolan-4-yl)methylacrylate (manufactured by Osaka Organic Chemical Industry Ltd)

4-HBA: 4-hydroxybutyl acrylate (manufactured by Osaka Organic Chemical Industry Ltd)

SYA004: 10-hydroxydecyl acrylate (manufactured by Sanyu Chemical Co., Ltd.)

HEA: Hydroxy ethyl acrylate

Omnirad 819: Phenylbis(2,4,6-trimethylbenzoyl)phosphine oxide (manufactured by IGM Resins)

Omnirad 184: 1-hydroxy cyclohexyl-phenylketone (manufactured by IGM Resins)

### 2. Evaluation of Resin Composition and Adhesive Member

Tables 3 and 4 show the results of evaluating viscosity and coating properties of the resin compositions of Examples (EX1-EX5) and Comparative Examples (CE1-CE6). In some embodiments, the glass transition temperature, haze, haze change rate, moisture absorption rate, and 180° peel force of a cured product (i.e., adhesive member) of the resin composition were evaluated, and the results are shown in Tables 3 and 4. In some embodiments, the concentration (mol %) of a hydroxy group-containing (meth)acrylate included in the resin composition was calculated and shown in Tables 3 and 4.

### Measurement of Viscosity of Resin Composition

In accordance with JIS K 2283, the viscosity of the resin composition was measured at a temperature of 30° C. The viscosity of the resin composition was measured at 50 rpm utilizing a viscometer TVE-25L (manufactured by TOKI SANGYO Co. Ltd.).

### Coating Properties of Resin Composition (Providing Inkjet Printing of Resin Composition)

The provision of inkjet printing of the resin composition was to evaluate the availability of coating, utilizing an inkjet printer device. The prepared resin composition was applied on soda-lime glass (manufactured by Central Glass Co., Ltd.) to have a thickness of 200 micrometer (μm) utilizing an inkjet printer (manufactured by MICROJET). The applied resin composition was cured through irradiation of UV light, and after the curing, the appearance of the cured product (i.e., adhesive member) was observed with the naked eye. In Tables 3 and 4, a case where the resin composition was stably ejected and applied at a substantially uniform thickness was marked with “⊚”, and a case where the resin composition was not ejected from the inkjet printer was marked with “X”.

### Concentration (Mol %) of Hydroxy Group-Containing (Meth)Acrylate

The concentration (mol %) of hydroxy group-containing (meth)acrylate was calculated through Equation 1a.

$$Concentration ( mol \% ) of hydroxy group - containing ( meth ) acrylate = number of moles of hydroxy group ‐ containing ( meth ) acrylate in resin composition \div number of moles of all compounds in resin composition \times 100 \qquad [ Equation 1 a ]$$

In Equation 1a, the number of moles of all compounds in the resin composition was calculated through Equation 1b.

$$Number of moles of all compounds in the resin composition = \sum \{ amount of each compound in the resin composition ( g ) \div molecular weight ( g / mol ) of each compound \} \qquad [ Equation 1 b ]$$

### Glass Transition Temperature of Adhesive Member

On a slide glass (slide glass S1112 manufactured by Matsunami Glass Ind., Ltd.), a release-treated PET film (NP100A manufactured by PANAC CO., LTD.) and a silicone rubber sheet having a hole of about 8 millimeter (mm) in diameter (manufactured by Tigers Polymer Corporation) were sequentially stacked. 28 microliter (μL) of the resin composition was dropped into the hole in the silicone rubber, and the rubber was irradiated with UV light, utilizing a UV-LED lamp having peaks at 405 nanometer (nm) and 365 nm so that the total amount of light was 220 millijoule per square centimeter (mJ/cm²) and 380 mJ/cm² for each. Thereafter, the release-treated PET film (NP100A manufactured by PANAC CO., Ltd.) and the slide glass (slide glass S1112 manufactured by Matsunami Glass Ind., Ltd.) were sequentially stacked. Using a UV-LED lamp having a peak at 395 nm, an upper side of the slide glass stacked after the irradiation of UV light was irradiated with UV light, so that the total amount of light was 4000 mJ/cm², to obtain an adhesive member (diameter: 8 mm, thickness: 500 μm). The glass transition temperature of the adhesive member was measured utilizing a dynamic viscoelasticity measuring device (MCR302 manufactured by Anton Paar Japan K.K). Measurement conditions were set to a frequency of 1 Hz, a temperature of −50° C. to 80° C., and a heating rate of 2 degree Celsius per minute (C/min).

### Initial Haze Value (%) of Adhesive Member

The prepared resin compositions of Examples and Comparative Examples were applied onto a slide glass (slide glass S1112 manufactured by Matsunami Glass Ind., Ltd.) to have a thickness of 200 μm, and wrapped with the slide glass. Thereafter, the resin compositions were cured through irradiation of UV light so that the total amount of light was 4000 mJ/cm² utilizing a UV-LED lamp having a peak at 395 nm. The haze value was measured in accordance with JIS K 7136:2000, a sample for evaluation of the haze value obtained therefrom, and the value was indicated as an initial HAZE value (%) of the cured resin product.

### Moisture Absorption Rate of Adhesive Member [%]

A sample having a diameter of 20 mm and a thickness of 5 mm for evaluating moisture absorption rate was prepared through the same manufacturing method as the adhesive member for measuring the glass transition temperature.

The sample for evaluating moisture absorption rate was stored for 72 hours in moist heat conditions of 85° C. and 85% RH, and then taken out and left for 1 hour for cooling at room temperature and humidity (temperature: 25° C., humidity: 50%). The moisture absorption rate (%) at a temperature of 85° C. and a humidity of 85% for 72 hours was calculated through Equation 1H.

$$Moisture absorption rate ( \% ) at a temperature of 85 ° C . and a humidity of 85 \% for 72 hours = \{ ( weight [ g ] after storage for 72 hours at a temperature of 85 ° C . and a humidity of 85 \% ) - ( weight [ g ] of initial sample ) \} \div ( weight [ g ] of initial sample ] ) \times 100 \qquad [ Equation 1 H ]$$

### Haze Change Rate (%) of Adhesive Member

A sample for evaluating the haze change rate was prepared in substantially the same manner as the method for measuring the haze value described herein, and stored for 72 hours in a moist heat conditions of a temperature of 85° C. and a humidity of 85%, and then taken out and left for 1 hour at room temperature and humidity for cooling.

Thereafter, the haze value of the sample for evaluating the haze change rate was measured in substantially the same manner as the initial haze value measurement. The haze change rate (%) after exposure for 72 hours at a temperature of 85° C. and a humidity of 85% was calculated through Equation 1c.

$$Haze change rate ( \% ) = haze value ( \% ) of sample for evaluating haze change rate exposed for 72 hours at a temperature of 85 ° C . and a humidity of 85 \% - initial haze value ( \% ) \qquad [ Equation 1 c ]$$

### 180° Peel Force of Adhesive Member

The prepared resin composition was applied on soda-lime glass (manufactured by Central Glass Co., Ltd.) to have a thickness of 200 μm. The applied resin composition was irradiated with UV light utilizing a UV-LED lamp having peaks at 405 nm and 365 nm so that the total amount of light was 220 mJ/cm² and 380 mJ/cm² for each to form a preliminary adhesive member. A PET film (manufactured by TOYOBO Co., Ltd., product name: A4360, thickness: 50 μm) was bonded on the formed preliminary adhesive member, and treated for 5 minutes at a temperature of 30° C. and a pressure of 0.5 megapascal (MPa), utilizing an automatic heating and pressure treatment device (manufactured by Chiyoda Electric Co., Ltd., product name: ACS-230). Thereafter, the preliminary adhesive member was irradiated with UV light so that the total amount of light was 4000 mJ/cm² to obtain a laminate including the adhesive member. The laminate was stored for 72 hours in a moist heat conditions of a temperature of 85° C. and a humidity of 85%, and then the 180° peel force of the obtained laminate was measured utilizing a tensile tester (TENSILON manufactured by A&D Company, Limited). The 180° peel force was measured at a tensile rate of 300 mm/min at a temperature of 85° C. and a humidity of 86%.

TABLE 3

| | EX1 | EX2 | EX3 | EX4 | EX5 |
|---|---|---|---|---|---|
| Viscosity of resin composition | 5.2 | 19.7 | 11.8 | 8.3 | 15.2 |
| [mPa · s, 30° C.] | | | | | |
| Provision of inkjet printing of resin | ⊚ | ⊚ | ⊚ | ⊚ | ⊚ |
| composition (coating property) | | | | | |
| [30° C.] | | | | | |
| Concentration of hydroxy group- | 12.5 | 14.2 | 5.7 | 19.9 | 14.2 |
| containing (meth)acrylate (mol %) | | | | | |
| Glass transition temperature of | −18 | 11 | 17 | −4 | 13 |
| adhesive member [° C.] | | | | | |
| Initial haze of adhesive member [%] | 0.4 | 0.3 | 0.4 | 0.8 | 0.5 |
| Moisture absorption rate of adhesive | 0.9 | 1.4 | 0.6 | 1.8 | 1.1 |
| member [%] | | | | | |
| Haze change rate of adhesive | 1.1 | 1.5 | 0.4 | 1.9 | 1.2 |
| member [%] | | | | | |
| 180° peel force of adhesive member | 540 | 720 | 420 | 980 | 860 |
| [Gf/25 mm, 85° C., 85%] | | | | | |

TABLE 4

| | CE1 | CE2 | CE3 | CE4 | CE5 | CE6 |
|---|---|---|---|---|---|---|
| Viscosity of resin composition | 29.4 | 13.5 | 12.8 | 14.7 | 8.3 | 5.6 |
| [mPa · s, 30° C.] | | | | | | |
| Provision of inkjet printing | Ejection | ⊚ | ⊚ | ⊚ | ⊚ | ⊚ |
| of resin composition (coating | defect | | | | | |
| property) [30° C.] | | | | | | |
| Concentration of hydroxy group- | 14.5 | 20.9 | 4.4 | 14.1 | 9.2 | 17.8 |
| containing (meth)acrylate (mol %) | | | | | | |
| Glass transition temperature of | 8 | 1 | 3 | 32 | −36 | −20 |
| adhesive member [° C.] | | | | | | |
| Initial haze of adhesive member [%] | 0.4 | 0.5 | 0.4 | 0.8 | 0.5 | 1.8 |
| Moisture absorption rate of adhesive | 1.2 | 2.2 | 1 | 1.4 | 3.1 | 1.5 |
| member [%] | | | | | | |
| Haze change rate of adhesive member | 0.8 | 2.7 | 0.6 | 0.7 | 6.7 | 2.6 |
| [%] | | | | | | |
| 180° peel force of adhesive member | 750 | 980 | 260 | 180 | 50 | 70 |
| [Gf/25 mm, 85° C., 85%] | | | | | | |

Referring to Table 3, it is seen that the resin compositions of Examples 1 to 5 (EX1-EX5) had a viscosity of 5 mPa·s or greater and 20 mPa·s or less at a temperature of 30° C. as measured by JISK 2283. It is seen that the resin compositions of Examples 1 to 5 (EX1-EX5) having a viscosity of 5 mPa·s or greater and 20 mPa·s or less were easily provided through inkjet printing. The resin compositions of Examples 1 to 5 (EX1-EX5) are the resin composition according to one or more embodiments, and the adhesive members formed from the resin compositions of Examples 1 to 5 (EX1-EX5) are the adhesive members according to one or more embodiments.

It is seen that the adhesive members formed from the resin compositions of Examples 1 to 5 (EX1-EX5) had a glass transition temperature of −20° C. or greater and 20° C. or less. It is seen that the adhesive members formed from the resin compositions of Examples 1 to 5 (EX1-EX5) exhibited excellent or suitable adhesion even when exposed to high temperature and humidity conditions.

In some embodiments, it is seen that the adhesive members formed from the resin compositions of Examples 1 to 5 (EX1-EX5) showed a high value of 180° peel force of 400 [gf/25 mm] or greater at a temperature of 85° C. and a humidity of 85%, and also, had a small rate of change in haze value even after being stored for 72 hours in a moist heat environment, thereby preventing or reducing degradation in viewability.

In comparison, referring to Table 4, it is seen that the resin composition of Comparative Example 1 (CE1) had a viscosity of greater than 20 mPa·s at a temperature of 30° C. as measured by JISK 2283. The resin composition of Comparative Example 1 (CE1) included urethane (meth)acrylate oligomer in an amount of greater than 10 wt % with respect to the total weight of the resin composition (Table 2) to show a high viscosity of greater than 20 mPa·s, indicating ejection failure from the inkjet printer.

It is seen that the adhesive member formed from the resin composition of Comparative Example 2 (CE2) had a high haze change rate when exposed to high temperature and humidity conditions, resulting in reduced viewability. This is because the resin composition of Comparative Example 2 (CE2) had greater absorption properties as the concentration of the hydroxy group-containing (meth)acrylate included in the resin composition was as high as 20.9 mol %.

It is seen that the adhesive members formed from the resin compositions of Comparative Examples 3 and 4 (CE3-CE4) had reduced 180° peel force at high temperature and humidity conditions. This is considered to be because the resin composition of Comparative Example 3 (CE3) had a low concentration of the hydroxy group-containing (meth)acrylate included in the resin composition as low as 4.4 mol %, resulting in reduced adhesion with respect to a glass substrate, which is a polar substrate. In some embodiments, the resin composition of Comparative Example 4 (CE4) failed to satisfy the glass transition temperature according to one or more embodiments, and had a high glass transition temperature, and thus had reduced adhesion with respect to a glass substrate to allow moisture to penetrate an interface between the glass substrate and the cured product (i.e., the adhesive member), resulting in reduced 180° peel force.

The adhesive member formed from the resin composition of Comparative Example 5 (CE5) had a high haze change rate at high temperature and humidity conditions to have significantly reduced viewability, and had reduced 180° peel force as well. The adhesive member formed from the resin composition of Comparative Example 5 (CE5) had a low glass transition temperature and had reduced resistance at high temperature and humidity conditions, resulting in greater absorption properties and reduced durability.

It is seen that the adhesive member formed from the resin composition of Comparative Example 6 (CE6) had a high haze change rate at high temperature and humidity conditions and had reduced 180° peel force. It is considered that the resin composition of Comparative Example 6 (CE6) did not include alicyclic (meth)acrylate having a glass transition temperature of about 80° C. or greater, and thus had reduced adhesion when exposed to high temperature and humidity conditions.

A resin composition of one or more embodiments may form an adhesive member through a process such as inkjet printing at room temperature. In some embodiments, the adhesive member formed of the resin composition of one or more embodiments does not have cloudiness and peeling even when exposed to high temperature and humidity conditions, and may thus exhibit excellent or suitable adhesive properties.

A display device of one or more embodiments includes the adhesive member formed of the resin composition described herein, and may thus provide excellent or suitable durability and display quality even at high temperature and humidity conditions.

Although the present disclosure has been described with reference to example embodiments of the present disclosure, it will be understood that the present disclosure should not be limited to these preferred embodiments but one or more suitable changes and modifications may be made by those skilled in the art without departing from the spirit and scope of the present disclosure as defined by the following claims and equivalents thereof.

Accordingly, the technical scope of the present disclosure is not intended to be limited to the contents set forth in the detailed description of the specification, but is intended to be defined by the appended claims and equivalents thereof.

What is claimed is:

1. A resin composition comprising:
a urethane (meth)acrylate oligomer containing two or more (meth)acryloyl groups; and
a monofunctional (meth)acrylate monomer,
wherein.
the monofunctional (meth)acrylate monomer comprises:
a hydroxy group-containing (meth)acrylate; and
an alicyclic (meth)acrylate having a glass transition temperature of about 80° C. or greater,
the resin composition comprises the urethane (meth)acrylate oligomer in an amount of at least about 1 wt % and at most about 10 wt % with respect to 100 wt % of the total resin composition,
the resin composition comprises the hydroxy group-containing (meth)acrylate in an amount of at least about 5 mol % and at most about 20 mol % with respect to 100 mol % of the total resin composition, and
the resin composition has a glass transition temperature of about −20° C. or greater and at most about 20° C. once cured.

2. The resin composition of claim 1, wherein the resin composition comprises the alicyclic (meth)acrylate in an amount of at least about 10 wt % and at most about 40 wt % with respect to 100 wt % of the total resin composition.

3. The resin composition of claim 1, wherein the hydroxy group-containing (meth)acrylate and the alicyclic (meth)acrylate each have a weight average molecular weight of about 150 gram per mole (g/mol) to about 300 g/mol.

4. The resin composition of claim 1, wherein the urethane (meth)acrylate oligomer has a weight average molecular weight of at least about 10,000 g/mol and at most about 40,000 g/mol.

5. The resin composition of claim 1, wherein the resin composition has a viscosity of at least about 5 millipascal second (mPa·s) and at most about 20 mPa·s at 30° C.

6. The resin composition of claim 1, wherein the monofunctional (meth)acrylate monomer further comprises at least one of an alkyl (meth)acrylate or a heteroalicyclic (meth)acrylate.

7. The resin composition of claim 6, wherein the alkyl (meth)acrylate and the heteroalicyclic (meth)acrylate each have a weight average molecular weight of about 150 g/mol to about 300 g/mol.

8. The resin composition of claim 1, further comprising a photo-initiator.

9. The resin composition of claim 8, wherein the photo-initiator comprises a radical polymerization initiator.

10. The resin composition of claim 1, wherein the resin composition is a solvent-free and photocurable resin composition.

11. An adhesive member provided as a cured product of a resin composition,
wherein the resin composition comprises:
a urethane (meth)acrylate oligomer containing two or more (meth)acryloyl groups; and
a monofunctional (meth)acrylate monomer,
the monofunctional (meth)acrylate monomer comprising:
a hydroxy group-containing (meth)acrylate; and
an alicyclic (meth)acrylate monomer having a glass transition temperature of at least about 80° C.,
the resin composition comprising the hydroxy group-containing (meth)acrylate in an amount of at least about 5 mol % and at most about 20 mol % with respect to 100 mol % of the total resin composition,
the resin composition having a viscosity of at least about 5 mPa·s and at most about 20 mPa·s at 30° C., and
the cured product having a glass transition temperature of at least about −20° C. and at most about 20° C.

12. The adhesive member of claim 11, wherein the adhesive member comprises the urethane (meth)acrylate oligomer in an amount of at least about 1 wt % or greater and at most about 10 wt % with respect to 100 wt % of the total resin composition.

13. The adhesive member of claim 11, wherein the urethane (meth)acrylate oligomer has a weight average molecular weight of at least about 10,000 g/mol and at most about 40,000 g/mol.

14. The adhesive member of claim 11, wherein the adhesive member has a haze of at most about 1% at a thickness of at most about 200 micrometer (μm).

15. The adhesive member of claim 11, wherein the adhesive member has a haze change rate of at most about 2% in Equation 1:
$$haze change rate ( \% ) = H 2 - H 1 \qquad [ Equation 1 ]$$
wherein in Equation 1, H1 indicates a haze value (unit: %) immediately after formation of the cured product, and H2 indicates a haze value (unit: %) after the adhesive member is exposed for about 72 hours at a temperature of about 85° C. and a humidity of about 85%.

16. The adhesive member of claim 11, wherein the adhesive member has a moisture absorption rate of at most about 2% after being exposed for about 72 hours at a temperature of about 85° C. and a humidity of about 85%.

17. The adhesive member of claim 11, wherein the adhesive member has a 180° peel force of at least about 400 gram-force per 25 millimeter (gf/25 mm) with respect to a glass substrate and/or a polymer substrate after the adhesive member is exposed for about 72 hours at a temperature of about 85° C. and a humidity of about 85%.

18. The adhesive member of claim 11, wherein the monofunctional (meth)acrylate monomer further comprises at least one of an alkyl (meth)acrylate or a heteroalicyclic (meth)acrylate.

19. The adhesive member of claim 18, wherein the alkyl (meth)acrylate and the heteroalicyclic (meth)acrylate each have a weight average molecular weight of about 150 g/mol to about 300 g/mol.

20. The adhesive member of claim 11, wherein the resin composition further comprises a photo-initiator.

21. A display device comprising:
a display panel;
a window on the display panel; and
an adhesive member between the display panel and the window and comprising a polymer derived from a resin composition,
wherein the resin composition comprises a urethane (meth)acrylate oligomer containing two or more (meth)acryloyl groups, and a monofunctional (meth)acrylate monomer,
the monofunctional (meth)acrylate monomer comprises a hydroxy group-containing (meth)acrylate and an alicyclic (meth)acrylate having a glass transition temperature of at most about 80° C.,
the resin composition comprises the urethane (meth)acrylate oligomer in an amount of at least about 1 wt % and at most about 10 wt % with respect to 100 wt % of the total resin composition,
the resin composition comprises the hydroxy group-containing (meth)acrylate in an amount of at least about 5 mol % or greater and at most about 20 mol % with respect to 100 mol % of the total resin composition, and
the adhesive member has a glass transition temperature of at least about −20° C. and at most about 20° C.

22. The display device of claim 21, wherein the adhesive member has a thickness of about 50 μm to about 200 μm.

23. The display device of claim 22, wherein the adhesive member has a haze of at most about 1%.

24. The display device of claim 21, wherein the adhesive member has a moisture absorption rate of at most about 2% after being exposed for about 72 hours at a temperature of about 85° C. and a humidity of about 85%.

25. The display device of claim 21, wherein the adhesive member has a 180° peel force of at least about 400 gf/25 mm with respect to a glass substrate or to a polymer substrate, after the adhesive member is exposed for about 72 hours at a temperature of about 85° C. and a humidity of about 85%.

26. The display device of claim 21, further comprising a light control layer between the adhesive member and the window, and
an optical adhesive layer between the light control layer and the window,
wherein the optical adhesive layer comprises a polymer derived from the resin composition.
